(19) United States
(12) Patent Application Publication
(10) Pub. No.: US 2009/0108395 A1
(43) Pub. Date: Apr. 30, 2009

(54) SEMICONDUCTOR DEVICE HAVING INCREASED ACTIVE REGION WIDTH AND METHOD FOR MANUFACTURING THE SAME

(76) Inventor: Shin Gyu CHOI, Seoul (KR)

Correspondence Address: LADAS & PARRY LLP, 224 SOUTH MICHIGAN AVENUE, SUITE 1600, CHICAGO, IL, 60604, US

(21) Appl. No.: 12/118,054

(22) Filed: May 9, 2008

(30) Foreign Application Priority Data
Oct. 31, 2007 (KR) 10-2007-0110610

(51) Int. Cl. H01L 29/06; H01L 21/762

(52) U.S. Cl. 257/506; 438/429; 257/E29.02; 257/E21.571

(57) ABSTRACT

The disclosed semiconductor device includes a plurality of active patterns including first active patterns which protrude from a semiconductor substrate and have a first width and second active patterns which are connected to upper ends of the respective first active patterns and have a second width greater than the first width. The semiconductor device further includes isolation patterns respectively located between the active patterns to insulate the active patterns from one another.

### CROSS-REFERENCE TO RELATED APPLICATIONS

The present application claims priority to Korean patent application number 10-2007-0110610 filed on Oct. 31, 2007, which is incorporated herein by reference in its entirety.

### BACKGROUND OF THE INVENTION

The present invention relates to a semiconductor device and a method for manufacturing the same, and more particularly, to a semiconductor device and a method for manufacturing the same which can improve operation characteristics and increase a manufacturing yield.

As the semiconductor device abruptly shrinks, the channel length and the channel width of the transistor decrease, and the doping concentration of a junction region and junction leakage current increase. In an effort to increase the channel length and the channel width of the transistor, research has actively been conducted to realize a semiconductor device having a three-dimensional channel structure.

For example, a fin transistor has been disclosed in the related art. The fin transistor is formed by etching an isolation layer such that the active regions protrude, and gates are formed to surround the protruded active regions. Advantages of a semiconductor device having such fin transistor include increased channel width, improved current drive characteristic through channels, and an increased threshold voltage margin.

Meanwhile, an isolation structure for delimiting the active regions is formed through a shallow trench isolation (STI) process. In the STI process trenches are defined in isolation regions, and the trenches are filled in through a gap-fill process by an insulation layer.

However, in the conventional art, it is difficult to secure a gap-fill margin, because the gap-fill process is conducted after defining the trenches so as to form the isolation structure. Also, as semiconductor devices trend toward high integration, channel width is increased which results in a decreased current amount and an increased channel resistance. In addition, in the conventional semiconductor device contact resistance increases because it is difficult to maintain the capacity of storage nodes and to secure open area margins of storage node contacts and bit line contacts.

### SUMMARY OF THE INVENTION

Embodiments of the present invention are directed to a semiconductor device and a method for manufacturing the same which can improve operation characteristics and increase a manufacturing yield.

A semiconductor device comprises a plurality of active patterns, each active patterns including a first active pattern having a first width and protruding from a semiconductor substrate, the first active patter having an upper surface and sidewalls adjacent to the upper surface and second active pattern which are connected to upper end of the the first active pattern and having a second width greater than the first width; and isolation pattern formed around each active pattern to insulate each active pattern from the other active patterns.

The second active patterns comprise a selective epitaxial growth layer.

The second active pattern is formed to be connected with upper surfaces and portions of sidewalls of the first active patterns.

A method for manufacturing a semiconductor device comprises the steps of forming a plurality of first protruded active patterns on a surface of a semiconductor substrate; forming an isolation pattern on the semiconductor substrate including the first protruded active patterns, the isolation pattern having openings which expose the first active patterns; enlarging the openings of the isolation pattern; and forming second active pattern, having a width greater than the first active pattern, in the enlarged openings.

The isolation pattern is formed from an insulation layer which is formed through any one of an HDP deposition process, an SOD process and an SOG process.

The step of enlarging the openings of the isolation pattern is implemented through an isotropic etching process.

The step of enlarging the openings of the isolation pattern is implemented to expose upper surfaces and portions of sidewalls of the first active patterns.

The step of forming the second active patterns comprises the steps of forming a selective epitaxial growth layer from the first active patterns on the isolation pattern including the openings; and removing the selective epitaxial growth layer until the isolation pattern is exposed.

The step of removing the selective epitaxial growth layer is implemented through a CMP process.

A method for manufacturing a semiconductor device comprises the steps of forming an insulation layer on a semiconductor substrate; patterning the insulation layer and the semiconductor substrate to form first active patterns which protrude from the semiconductor substrate and insulation layer patterns which are positioned on the first active patterns; forming isolation pattern on the semiconductor substrate between the first active patterns to expose upper surfaces of the insulation layer patterns; removing the insulation layer patterns to define openings which expose upper surfaces of the first active patterns; removing portions of sidewalls of the isolation pattern which face the openings to enlarge a width of the openings; and forming second active patterns, having a width greater than the first active patterns, in the enlarged openings.

The insulation layer can be an oxide layer or a nitride layer, as a single layer.

The insulation layer can be an oxide layer and a nitride layer, as a double layer.

The isolation pattern is formed from an insulation layer which is formed through any one of an HDP deposition process, an SOD process and an SOG process.

The step of removing the insulation layer patterns is implemented using at least one of a cleaning solution containing phosphoric acid and a cleaning solution containing fluoric acid.

The step of removing the isolation pattern for enlarging the width of the openings is implemented through an isotropic etching process.

The step of enlarging the width of the openings of the isolation pattern is implemented to expose the upper surfaces and portions of sidewalls of the first active patterns.

The step of forming the second active patterns comprises the steps of forming a selective epitaxial growth layer from the first active patterns on the isolation pattern including the openings; and removing the selective epitaxial growth layer until the isolation patterns are exposed.

The step of removing the selective epitaxial growth layer is implemented through a CMP process.

### BRIEF DESCRIPTION OF THE DRAWINGS

FIG. 1 is a sectional view illustrating a semiconductor device in accordance with an embodiment of the present invention.

FIGS. 2A through 2H are sectional views illustrating the processes of a method for manufacturing a semiconductor device in accordance with embodiment of the present invention.

FIG. 3 is a plan view of FIG. 2A.

FIG. 4 is a plan view of FIG. 2B.

FIG. 5 is a plan view of FIG. 2H.

### DESCRIPTION OF SPECIFIC EMBODIMENTS

In the present invention, after the first active patterns are formed to protrude from a semiconductor substrate, second active patterns connected with the first active patterns and having a width greater than that of the first active patterns, are formed from a selective epitaxial growth layer.

In the present invention wide active regions can be obtained as a result of the forming of the second active patterns, and current amount can increase as channel width increases and channel resistance decreases. Also, in the present invention, due to the fact that the wide active regions can be obtained, contact resistance can be decreased because the open area margins of storage node contacts and bit line contacts can be increased,. Accordingly, in the present invention, it is possible to realize a semiconductor device which has an improved operation characteristic and an increased manufacturing yield.

Hereafter, specific embodiments of the present invention will be described with reference to the attached drawings.

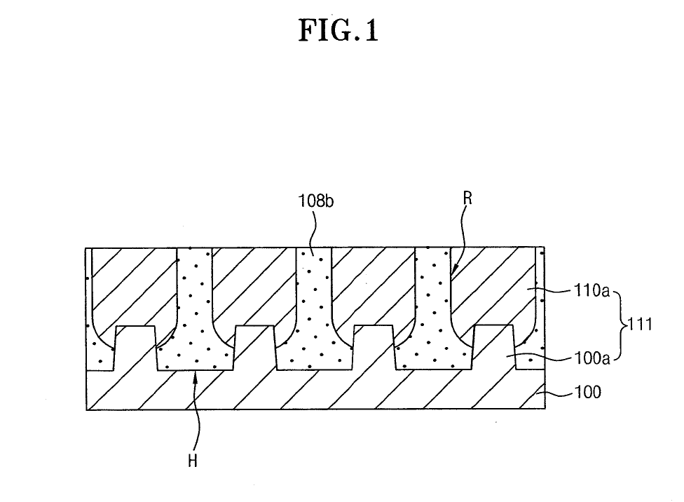

FIG. 1 is a sectional view illustrating a semiconductor device in accordance with an embodiment of the present invention.

Referring to FIG. 1, isolation groove H is defined on the surface of a semiconductor substrate 100. Due to the presence of the isolation groove H, first active patterns 100a, which have a first width and the shape of an island when viewed from the top, are formed to protrude from the surface of the semiconductor substrate 100.

An isolation pattern 108b is formed on the first active patterns 100a and the isolation groove H. Recess portions R are defined in the isolation pattern 108b to expose the upper surfaces and portions of the side surfaces of the first active patterns 100a, and the recess portions R have a width greater than the first width of the first active patterns 100a. Second active patterns 110a, which have a second width greater than the first width of the first active patterns 100a, are formed in the recess portions R.

The second active patterns 110a are located on the upper ends of the first active patterns 100a and are formed to be connected with the upper surfaces and portions of the side surfaces of the first active patterns 100a. The first active patterns 100a and the second active patterns 110a constitute active patterns 111. The second active patterns 110a are formed as a selective epitaxial growth layer on the first active patterns 100a through a selective epitaxial growth process.

Therefore, in the present invention the second active patterns 110a, having the second width greater than the first width of the first active patterns 100a, are formed thereby increasing the size of the active regions. As a result of the increased size of the active regions, a channel width can be increased in subsequent processes for forming recess gates. Therefore, in the present invention, channel resistance decreases, and current amount increases. Further, in the present invention, the size of the active regions is increased, and therefore the capacity of storage nodes can be maintained, and the open area margins of storage node contacts and bit line contacts are increased thereby decreasing contact resistance. As a result, a semiconductor device according to the present invention has improved operation characteristic and an increased manufacturing yield.

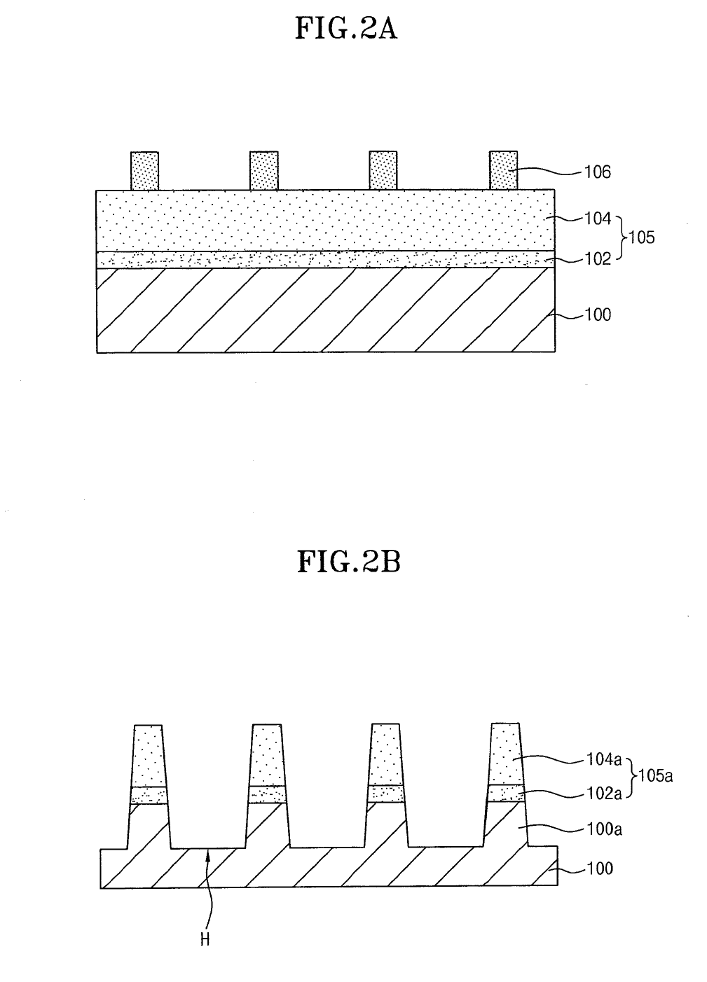

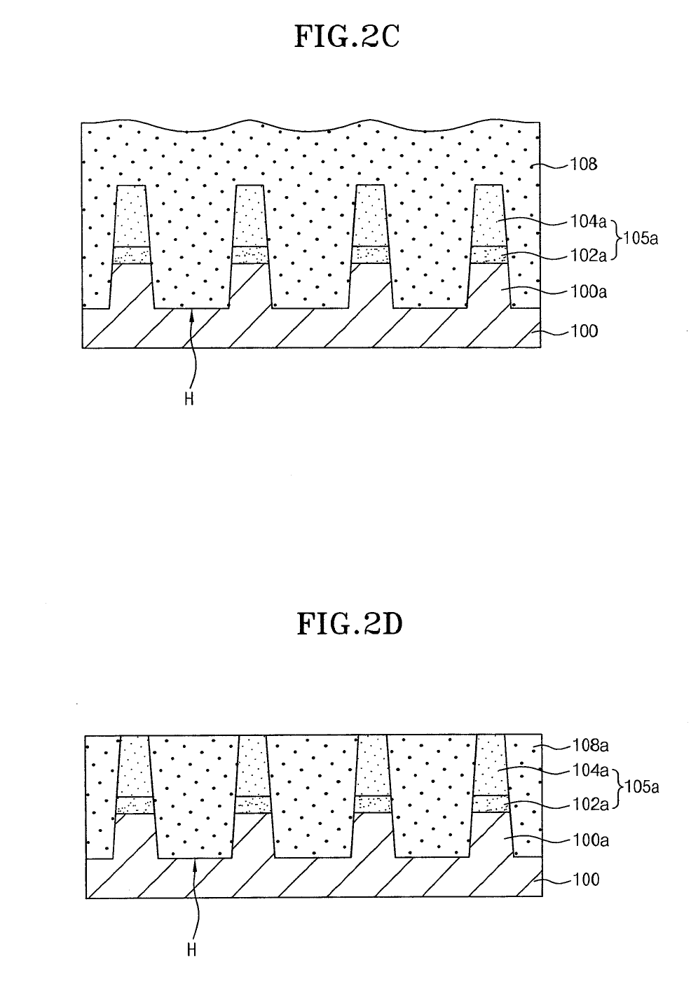

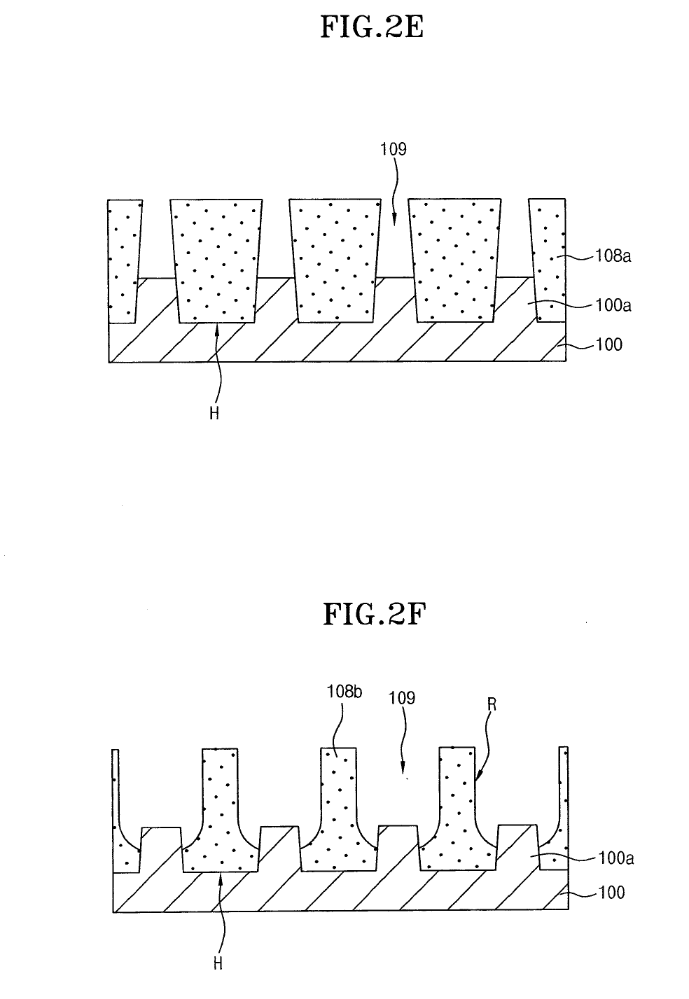

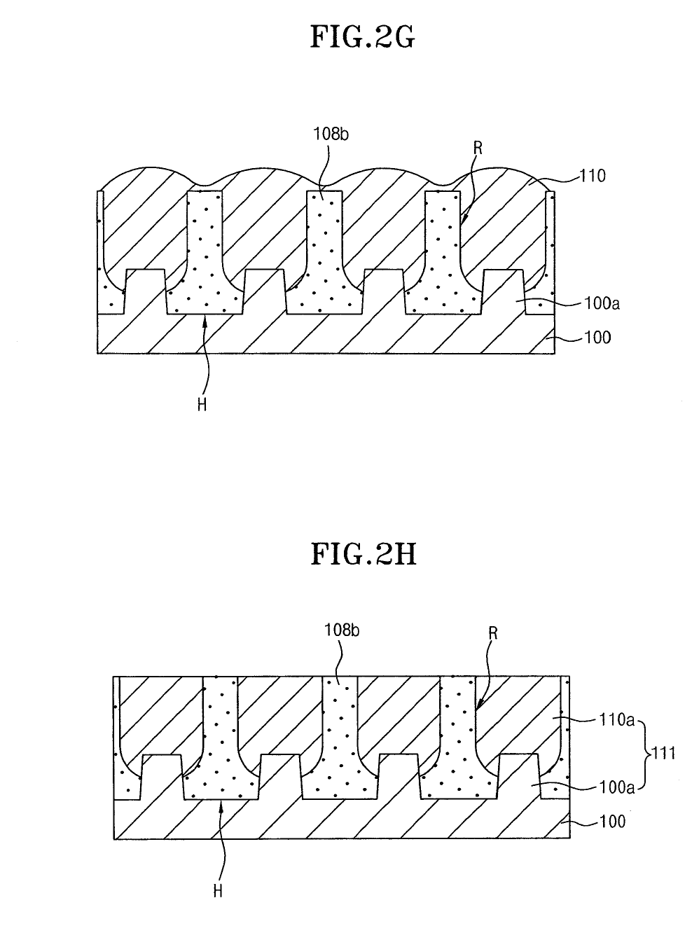

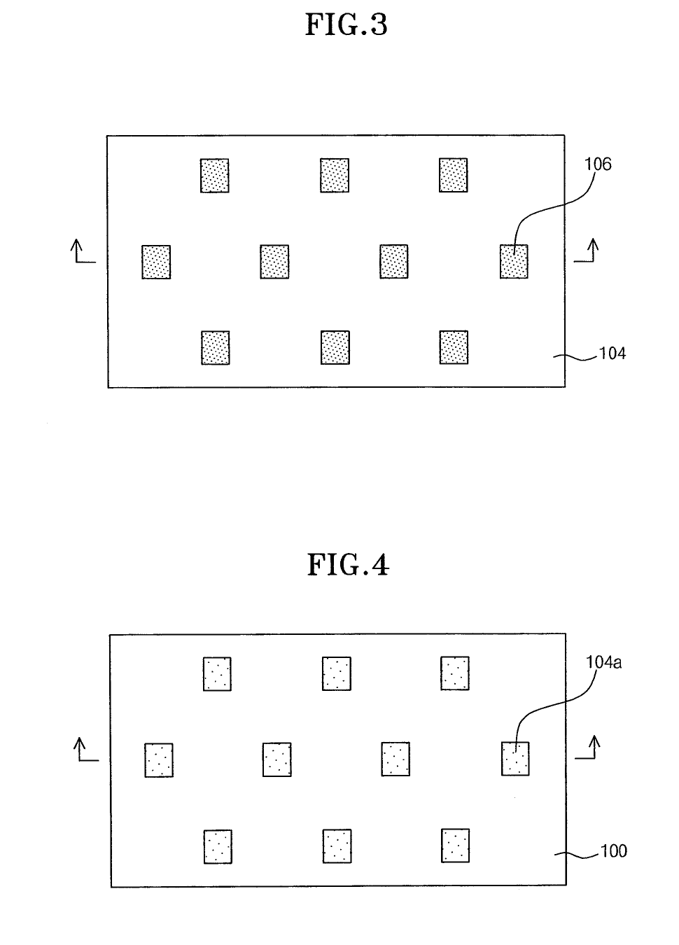

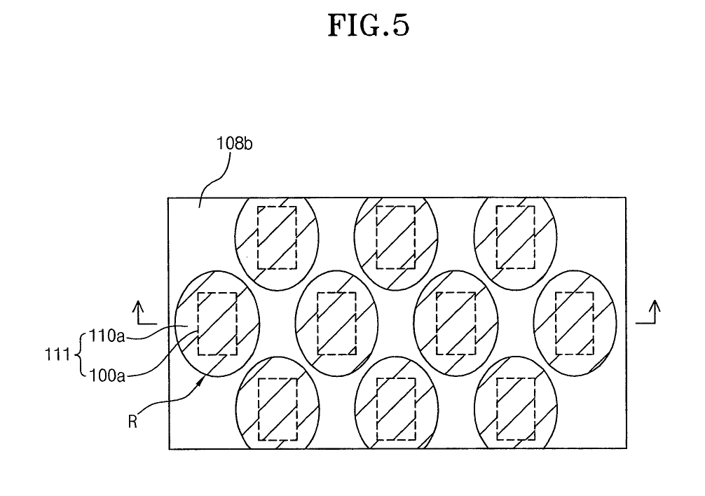

FIGS. 2A through 2H are sectional views illustrating the processes of a method for manufacturing a semiconductor device in accordance with another embodiment of the present invention, FIG. 3 is a plan view of FIG. 2A, FIG. 4 is a plan view of FIG. 2B, and FIG. 5 is a plan view of FIG. 2H.

Referring to FIGS. 2A and 3, an insulation layer 105 is formed on a semiconductor substrate 100 which has active regions and isolation region. The insulation layer 105 can be formed as any one of a single layer, a double layer, and a multiple layer. For example, the insulation layer 105 can be an oxide layer 102 or a nitride layer 104 as a single layer. Preferably, the insulation layer 105 can be the oxide layer 102 and the nitride layer 104 as a double layer. In order to form isolation pattern, mask pattern 106 is formed on the nitride layer 104. The mask pattern 106 is formed of a photoresist.

Referring to FIGS. 2B and 4, the insulation layer 105, comprising the double layer of the oxide layer 102 and the nitride layer 104, is patterned through an etching process using the mask patterns 106 as an etch mask. As a result of the etching process insulation layer patterns 105a, comprising oxide layer patterns 102a and nitride layer patterns 104a, are formed. An isolation groove H is defined on the surface of the semiconductor substrate 100 through an etching process using the insulation layer patterns 105a as an etch mask. First active patterns 100a having the shape of an island and a first width are formed on the surface of the semiconductor substrate 100 to protrude from the semiconductor substrate 100. The mask patterns 106 are then removed.

Referring to FIG. 2C, a device isolating insulation layer 108 is formed on the semiconductor substrate 100 including the first active patterns 100a to fill the isolation groove H. The device isolating insulation layer 108 is formed through any one of an high density plasma (HDP) deposition process, an spin-on dielectric (SOD) process and an spin-on glass SOG process. The device isolating insulation layer 108 can be an oxide layer.

Referring to FIG. 2D, isolation pattern 108a is formed by removing the device isolating insulation layer 108 until the nitride layer patterns 104a of the insulation layer patterns 105a are exposed. The removal of the device isolating insulation layer 108 is implemented, for example, through a chemical mechanical polishing (CMP) process or an etch-back process.

Referring to FIG. 2E, openings 109 are defined by removing the insulation layer patterns 105a from the first active patterns 100a. The openings 109 expose the upper surfaces of the first active patterns 100a. The removal of the insulation layer patterns 105a may be implemented in a number of different ways. For example, the insulation layer patterns 105a may be removed by using a cleaning solution containing fluoric acid when the insulation layer patterns 105a comprise the single layer of the oxide layer patterns, using a cleaning solution containing phosphoric acid when the insulation layer patterns comprise the single layer of the nitride layer patterns, or sequentially using solutions respectively containing fluoric acid and phosphoric acid when the insulation layer patterns comprise the double layer of the oxide layer patterns and the nitride layer patterns.

Referring to FIG. 2F, the sidewalls of the respective isolation pattern 108a, which face the openings 109, are etched until portions of the sidewalls of the first active patterns 100a are exposed. According to this, recess portions R, which have a width greater than the first width of the first active patterns 100a, are defined over the first active patterns 100a. The reference numeral 108b designates isolation pattern which are etched to expose the portions of the sidewalls of the first active patterns 100a. Here, the removal of the isolation pattern 108a is implemented, for example, through an isotropic etching process.

Referring to FIG. 2G, a selective epitaxial growth layer 110 is formed on the isolation pattern 108b to fill the recess portions R, through a selective epitaxial growth process which uses the first active patterns 100a that protrude from the semiconductor substrate 100.

Referring to FIGS. 2H and 5, the selective epitaxial growth layer 110 is removed until the isolation pattern 108b is exposed, thereby forming second active patterns 110a, which have a second width greater than the first width of the first active patterns 100a. As a result, active patterns 111 composed of the first active patterns 100a and the second active patterns 110a are formed. Here, the removal of the selective epitaxial growth layer 110 for forming the second active patterns 110a is implemented, for example, through a CMP process.

As described above, in the present invention, the second active patterns 110a have a width greater than that of the first active patterns 100a, and therefore the size of the active regions can be increased and in subsequent processes for forming recess gates a channel width can be increased. According to this, in the present invention the operation characteristic of a semiconductor device can be improved, due to increased current amount and decreased channel resistance. Further, in the present invention, since the size of the active regions can be increased, open area margins can be secured in subsequent processes for forming storage node contacts and bit line contacts, whereby the manufacturing yield of a semiconductor device can be increased.

Thereafter, while not shown in the drawings, the manufacture of the semiconductor device according to the embodiment of the present invention is completed by sequentially conducting a series of subsequent processes well known to those in the art.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a plurality of active patterns, each active pattern including:
a first active pattern having a first width and protruding from a semiconductor substrate, the first active pattern having an upper surface and sidewalls adjacent to the upper surface; and
a second active pattern connected to an upper end of the first active pattern and having a second width greater than the first width;
and
an isolation pattern formed around each active pattern to insulate each active pattern from the other active patterns.

2. The semiconductor device according to claim 1, wherein the second active pattern comprise a selective epitaxial growth layer.

3. The semiconductor device according to claim 1, wherein the second active pattern is formed to be connected with upper surfaces and portions of sidewalls of the first active patterns.

4. A method for manufacturing a semiconductor device, comprising the steps of:
forming a plurality of first protruded active patterns on a surface of a semiconductor substrate;
forming isolation pattern on the semiconductor substrate including the first protruded active patterns, the isolation pattern having openings which expose the first active patterns;
enlarging the openings of the isolation pattern; and
forming second active pattern, having a width greater than the width of the first active pattern, in the enlarged openings.

5. The method according to claim 4, wherein the isolation pattern is formed from an insulation layer which is formed by any one of a high density plasma (HDP) deposition process, a spin-on dielectric (SOD) process, and a spin-on glass (SOG) process.

6. The method according to claim 4, wherein the step of enlarging the openings of the isolation pattern is implemented through an isotropic etching process.

7. The method according to claim 4, wherein the step of enlarging the openings of the isolation pattern is implemented to expose upper surfaces and portions of sidewalls of the first active patterns.

8. The method according to claim 4, wherein the step of forming the second active patterns comprises the steps of:
forming a selective epitaxial growth layer from the first active pattern on the isolation pattern including the openings; and
removing the selective epitaxial growth layer until the isolation pattern is exposed.

9. The method according to claim 7, wherein the step of removing the selective epitaxial growth layer is implemented through a chemical mechanical polishing (CMP) process.

10. A method for manufacturing a semiconductor device, comprising the steps of:
forming an insulation layer on a semiconductor substrate;
patterning the insulation layer and the semiconductor substrate to form first active patterns, which protrude from the semiconductor substrate, and insulation layer patterns which are positioned on the first active patterns;
forming isolation pattern on the semiconductor substrate between the first active patterns to expose upper surfaces of the insulation layer patterns;
removing the insulation layer patterns to define openings which expose upper surfaces of the first active patterns;
removing portions of sidewalls of the isolation pattern which face the openings to enlarge a width of the openings; and
forming second active patterns, having a width greater than the first active patterns, in the enlarged openings.

11. The method according to claim 10, wherein the insulation layer is formed as a single layer comprising an oxide layer or a nitride layer.

12. The method according to claim 10, wherein the insulation layer is formed as a double layer comprising an oxide layer and a nitride layer.

13. The method according to claim 10, wherein the isolation pattern is formed from the insulation layer which is formed through any one of an HDP deposition process, an SOD process, and an SOG process.

14. The method according to claim 10, wherein the step of removing the insulation layer patterns is implemented using at least one of a cleaning solution containing phosphoric acid and a cleaning solution containing fluoric acid.

15. The method according to claim 10, wherein the step of removing the isolation pattern for enlarging the width of the openings is implemented through an isotropic etching process.

16. The method according to claim 10, wherein the step of enlarging the width of the openings of the isolation pattern is implemented to expose the upper surfaces and portions of sidewalls of the first active patterns.

17. The method according to claim 10, wherein the step of forming the second active patterns comprises the steps of:
forming a selective epitaxial growth layer from the first active pattern on the isolation pattern including the openings; and
removing the selective epitaxial growth layer until the isolation pattern is exposed.

18. The method according to claim 17, wherein the step of removing the selective epitaxial growth layer is implemented through a CMP process.
